(19) United States
(12) Patent Application Publication
(10) Pub. No.: US 2025/0006577 A1
(43) Pub. Date: Jan. 2, 2025

(54) ELECTRONIC DEVICE AND MANUFACTURING METHOD THEREOF

(71) Applicant: Innolux Corporation, Miaoli County (TW)

(72) Inventors: Mei-Yen Chen, Miaoli County (TW); Ju-Li Wang, Miaoli County (TW); Yen-Fu Liu, Miaoli County (TW)

(73) Assignee: Innolux Corporation, Miaoli County (TW)

(21) Appl. No.: 18/675,129

(22) Filed: May 27, 2024

Related U.S. Application Data
(60) Provisional application No. 63/524,231, filed on Jun. 30, 2023.

(30) Foreign Application Priority Data
Mar. 26, 2024 (CN) 202410353184.3

(51) Int. Cl. H01L 23/31; H01L 23/00; H01L 23/40; H01L 23/498

(52) U.S. Cl. CPC H01L 23/3128; H01L 23/4006; H01L 23/49816; H01L 24/08; H01L 24/16; H01L 24/97; H01L 2224/08146; H01L 2224/08225; H01L 2224/16146; H01L 2224/16157; H01L 2224/97; H01L 2924/0665; H01L 2924/1434; H01L 2924/15311; H01L 2924/182

(57) ABSTRACT

An electronic device including an electronic element, an encapsulation layer, a circuit structure, a bonding element, and a bolt is provided. The encapsulation layer surrounds the electronic element. The circuit structure is electrically connected to the electronic element. The bonding element is electrically connected to the electronic element via the circuit structure. The bolt is disposed between the circuit structure and the encapsulation layer. A manufacturing method of an electronic device is also provided.

### CROSS-REFERENCE TO RELATED APPLICATION

This application claims the priority benefit of U.S. provisional application Ser. No. 63/524,231, filed on Jun. 30, 2023 and China application serial no. 202410353184.3, filed on Mar. 26, 2024. The entirety of each of the above-mentioned patent applications is hereby incorporated by reference herein and made a part of this specification.

### BACKGROUND

### Technical Field

The disclosure relates to an electronic device and a manufacturing method thereof.

### Description of Related Art

During the manufacturing process of an electronic device, such as chip transfer or packaging, the chip may be shifted due to factors such as process deviation or thermal expansion and contraction, causing the circuit structure formed on the chip to be misaligned with the chip, thereby affecting the electrical performance of the chip.

### SUMMARY

The disclosure provides an electronic device and a manufacturing method thereof that may help reduce the adverse effects caused by chip shift.

In an embodiment of the disclosure, an electronic device includes an electronic element, an encapsulation layer, a circuit structure, a bonding element, and a bolt. The encapsulation layer surrounds the electronic element. The circuit structure is electrically connected to the electronic element. The bonding element is electrically connected to the electronic element via the circuit structure. The bolt is disposed between the circuit structure and the encapsulation layer.

In another embodiment of the disclosure, an electronic device includes a packaging structure and a circuit structure. The packaging structure includes a first electronic element, a second electronic element, and an encapsulation layer surrounding the first electronic element and the second electronic element. The first electronic element is electrically connected to the second electronic element via the circuit structure. The circuit structure includes a first contact portion overlapped with a first pad of the first electronic element and a second contact portion overlapped with a second pad of the second electronic element. The first contact portion is aligned with the first pad, and the second contact portion is misaligned with the second pad.

In another embodiment of the disclosure, an electronic device includes an electronic element, an encapsulation layer, and a circuit structure. The encapsulation layer surrounds the electronic element. The circuit structure is electrically connected to the electronic element. The electronic element includes a plurality of pads, and the circuit structure includes a plurality of contact portions respectively overlapped with the plurality of pads. One contact portion in the plurality of contact portions is aligned with one corresponding pad, and another contact portion in the plurality of contact portions is misaligned with another corresponding pad.

In another embodiment of the disclosure, a manufacturing method of an electronic device includes: transferring a plurality of electronic elements onto a carrier board; forming an encapsulation layer surrounding the plurality of electronic elements; retrieving position information of at least one electronic element in the plurality of electronic elements; comparing the position information of the at least one electronic element with a reference value to obtain a shift amount; and forming a circuit structure on the plurality of electronic elements and the encapsulation layer, wherein the circuit structure includes a plurality of contact portions in contact with a plurality of pads of the plurality of electronic elements, and a position of each of the plurality of contact portions is compensated according to the shift amount, such that at least one in the plurality of contact portions is aligned with at least one corresponding pad.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view illustrating the transfer of a plurality of electronic elements onto a carrier board.

FIG. 2 is a schematic cross-sectional view corresponding to section line I-I′ in FIG. 1.

FIG. 3 is a schematic cross-sectional view illustrating the formation of an encapsulation layer surrounding a plurality of electronic elements.

FIG. 4 is a schematic cross-sectional view of a flipped carrier board.

FIG. 5 is a top schematic view illustrating retrieving position information of at least one electronic element in a plurality of electronic elements and comparing the position information of the at least one electronic element with a reference value to obtain a shift amount.

FIG. 6 is a schematic cross-sectional view illustrating circuit structures formed on a plurality of electronic elements and an encapsulation layer.

FIG. 7 is a schematic cross-sectional view illustrating cutting a circuit structure and an encapsulation layer.

FIG. 8 is a schematic cross-sectional view illustrating the formation of a bonding element on a circuit structure.

FIG. 9 is a schematic cross-sectional view of an electronic device according to some embodiments of the disclosure.

FIG. 10A to FIG. 10C are respectively schematic top views of the region RA, the region RB, and the region RC in FIG. 9.

FIG. 11A and FIG. 11B are respectively schematic top views of two electronic devices according to some other embodiments of the disclosure.

FIG. 12 is a schematic cross-sectional view of an electronic device according to some other embodiments of the disclosure.

### DESCRIPTION OF THE EMBODIMENTS

Reference will now be made in detail to the exemplary embodiments of the disclosure, and examples of the exemplary embodiments are illustrated in the accompanying drawings. Wherever possible, the same reference numerals are used in the figures and the descriptions to refer to the same or similar portions.

Certain terms are used throughout the specification and attached claims of the disclosure to refer to particular elements. Those having ordinary skill in the art should understand that manufacturers of electronic devices may refer to the same element with different names. The specification does not intend to distinguish between elements having the same function but different names. In the following specification and claims, words such as “comprising” and “including” are open-ended words, so they should be interpreted as meaning “comprising but not limited to . . . ”

The directional terms mentioned herein, such as “upper”, “lower”, “front”, “rear”, “left”, “right”, etc., refer to the directions of the drawings. Accordingly, the directional terms used are for illustration, not for limiting the disclosure. In the drawings, each figure illustrates the general characteristics of methods, structures, and/or materials used in particular embodiments. However, these drawings should not be interpreted as defining or limiting the scope or nature encompassed by these embodiments. For example, the relative dimensions, thicknesses, and positions of layers, regions, and/or structures may be reduced or exaggerated for clarity.

It should be understood that, relative terms, such as “lower” or “bottom” or “higher” or “top”, may be used in each embodiment to describe the relative relationship of one element of the figure to another element. It may be understood that if the device in the figures is turned upside down, elements described as being on the “lower” side are then elements described as being on the “higher” side. The embodiments of the disclosure may be understood together with the accompanying drawings, which are also considered to be part of the disclosure description.

A structure (or layer, element, substrate) described in the disclosure as being located on/over another structure (or layer, element, substrate) may mean that the two structures are adjacent and directly connected, or it may mean that the two structures are adjacent rather than directly connected. Indirect connection means that there is at least one intermediate structure (or intermediate layer, intermediate element, intermediate substrate, intermediate space) between two structures. The lower surface of one structure is adjacent to or directly connected to the upper surface of the intermediate structure, and the upper surface of the other structure is adjacent to or directly connected to the lower surface of the intermediate structure. The intermediate structure may be formed by a single-layer or multi-layer physical structure or non-physical structure without limitation. In the disclosure, when a structure is disposed “on” other structures, it may mean that a certain structure is “directly” on the other structures, or that a certain structure is “indirectly” on the other structures, that is, there is at least one structure interposed between a certain structure and the other structures.

The terms “about”, “substantially”, or “essentially” are generally interpreted as being within 10% of a given value or range, or as being within 5%, 3%, 2%, 1%, or 0.5% of a given value or range. Moreover, the terms “the range is from the first value to the second value” and “the range is between the first value and the second value” mean that the range includes the first value, the second value, and other values in between.

Words such as “first” and “second” used in the specification and claims are used to modify elements, which do not themselves imply and represent that the (or these) elements have any previous ordinal numbers, nor do they imply an order of a certain element with another element, or an order in manufacturing methods. These ordinal numbers are used to clearly distinguish an element having a certain designation from another element having the same designation. The same wording may be not used in the claims and the specification. Accordingly, the first member in the specification may be the second member in the claims.

The electrical connection or coupling described in the disclosure may both refer to direct connection or indirect connection. In the case of a direct connection, the terminals of elements on two circuits are connected directly or connected to each other by a conductor segment. In the case of indirect connection, there are switches, diodes, capacitors, inductors, resistors, other suitable elements, or a combination of the above elements between the terminals of the elements on the two circuits, but the disclosure is not limited thereto.

In the disclosure, the thickness, length, and width may be measured by using an optical microscope (OM), and the thickness or width may be measured by a cross-sectional image in an electron microscope, but the disclosure is not limited thereto. In addition, any two values or directions used for comparison may have a certain error. Moreover, the terms “the given range is from the first value to the second value”, “the given range falls within the range from the first value to the second value”, or “the given range is between the first value and the second value” mean that the given range includes the first value, the second value, and other values in between. If the first direction is perpendicular to the second direction, the angle between the first direction and the second direction may be between 80 degrees and 100 degrees. If the first direction is parallel to the second direction, the angle between the first direction and the second direction may be between 0° and 10°.

Unless otherwise defined, all terms (including technical and scientific terms) used herein have the same meaning as commonly understood by those having ordinary skill in the art to which this disclosure belongs. It may be understood that these terms, such as those defined in commonly used dictionaries, should be interpreted as having a meaning consistent with the background or context of the related techniques and the disclosure, and should not be interpreted in an idealized or overly formal manner, unless otherwise defined in the embodiments of the disclosure.

In the disclosure, the electronic device may include a power device, a semiconductor packaging device, a display device, a backlight device, an antenna device, a packaging device, a sensing device, or a tiling device, but the disclosure is not limited thereto. The electronic device may be a bendable or flexible electronic device. The display device may be a non-self-luminous display device or a self-luminous display device. The display device may include, for example, liquid crystal, light-emitting diode, fluorescence, phosphor, quantum dot (QD), other suitable display media, or a combination of the above. The antenna device may include, for example, a reconfigurable intelligent surface (RIS), a frequency-selective surface (FSS), a radio-frequency filter (RF-filter), a polarizer, a resonator, or an antenna, etc. The antenna may be a liquid-crystal antenna or a varactor diode antenna. The sensing device may be a sensing device for sensing capacitance, light, heat, or ultrasound, but the disclosure is not limited thereto. In the disclosure, the electronic device may include an electronic element. The electronic element may include a passive element and an active element, such as a know good die (KGD), a capacitor, a resistor, an inductor, a diode, a transistor, a varactor diode, a variable capacitor, a filter, a sensor, a microelectromechanical system element (MEMS), a liquid-crystal chip, a structure of a semiconductor-related process, or a structure of a semiconductor-related process disposed on a substrate (such as polyimide, glass, silicon substrate, or other suitable substrate materials), but the disclosure is not limited thereto. The diode may include a light-emitting diode, a varactor diode, or a photodiode. The light-emitting diode may include, for example, an organic light-emitting diode (OLED), a mini LED, a micro LED, or a quantum dot LED, but the disclosure is not limited thereto. The tiling device may be, for example, a display tiling device or an antenna tiling device, but the disclosure is not limited thereto. It should be noted that the electronic device may be any arrangement and combination of the above, but the disclosure is not limited thereto. The packaging device may be suitable for a wafer-level packaging (WLP) technique or a panel-level packaging (WLP) technique, such as the packaging device of a chip first process or an RDL first process. Moreover, the shape of the electronic device may be rectangular, circular, polygonal, a shape having curved edges, or other suitable shapes. The electronic device may have a peripheral system such as a driving system, a control system, and a light source system to support a display device, an antenna device, a wearable device (for example, including augmented reality or virtual reality), a vehicle-mounted device (for example, including a car windshield), or a tiling device. The following embodiments use packaging devices as examples to illustrate some implementation types of the electronic device, but the disclosure is not limited thereto. According to an embodiment of the disclosure, the provided manufacturing method of the electronic device may be applied, for example, to a wafer-level package (WLP) or a panel-level package (PLP) process, and a chip-first process or a chip-last (RDL-first) process may be adopted, which is further described in detail below. According to an embodiment of the disclosure, the packaging structure of the electronic device may include a system on package (SoC), a system in package (SiP), an antenna in package (AiP), or a combination thereof, but the disclosure is not limited thereto.

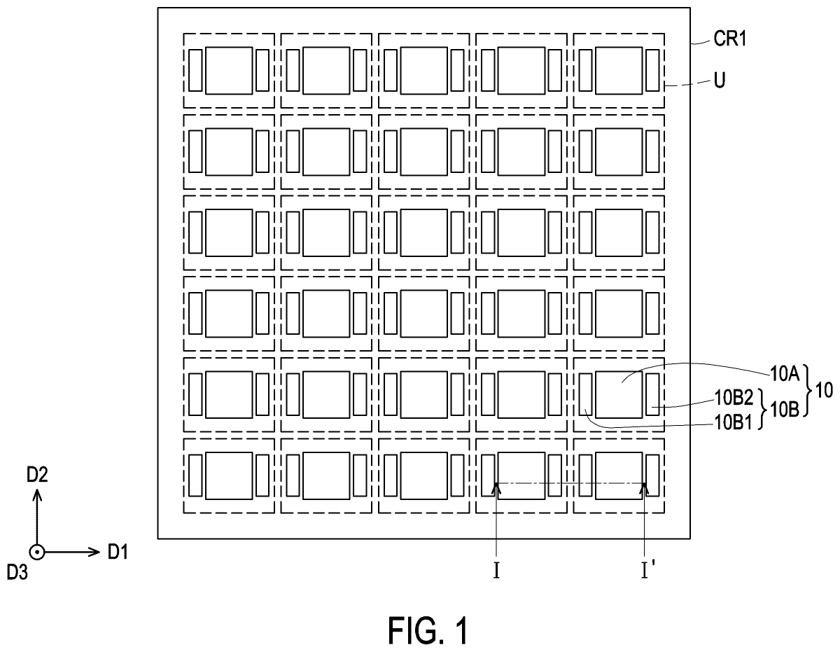

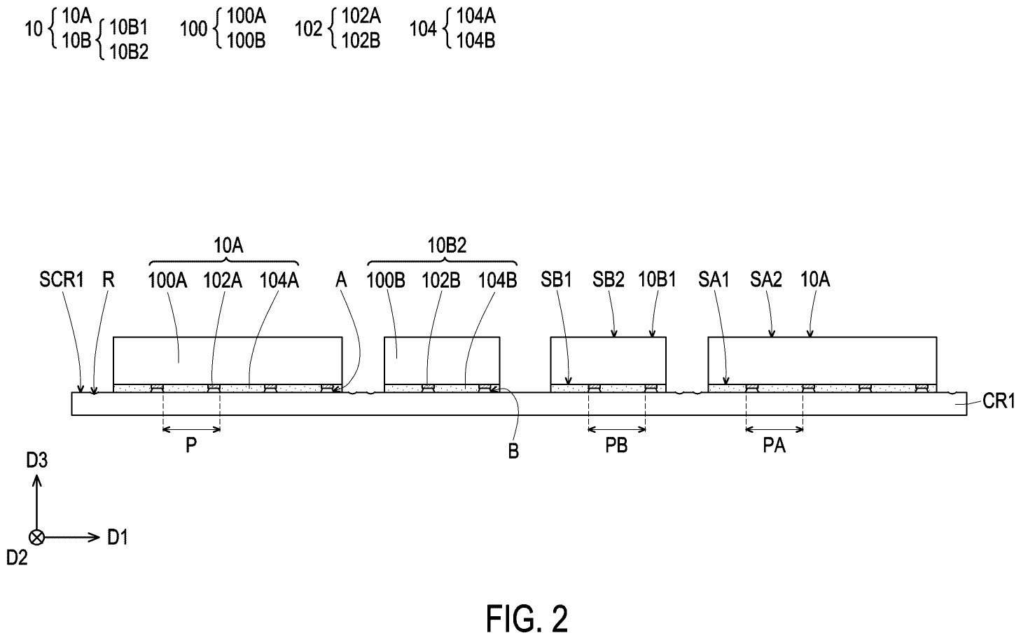

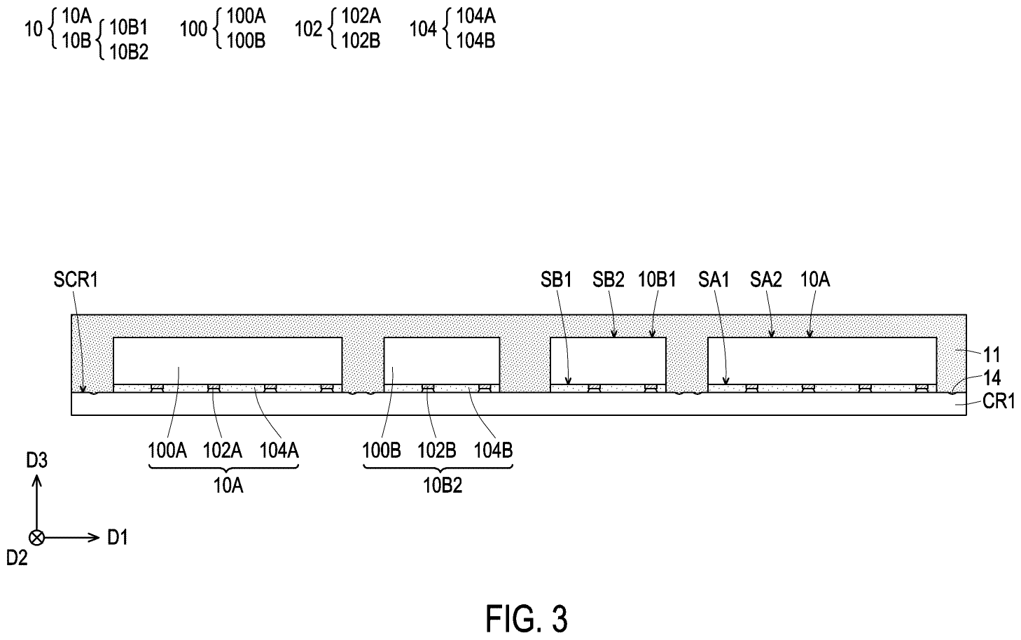

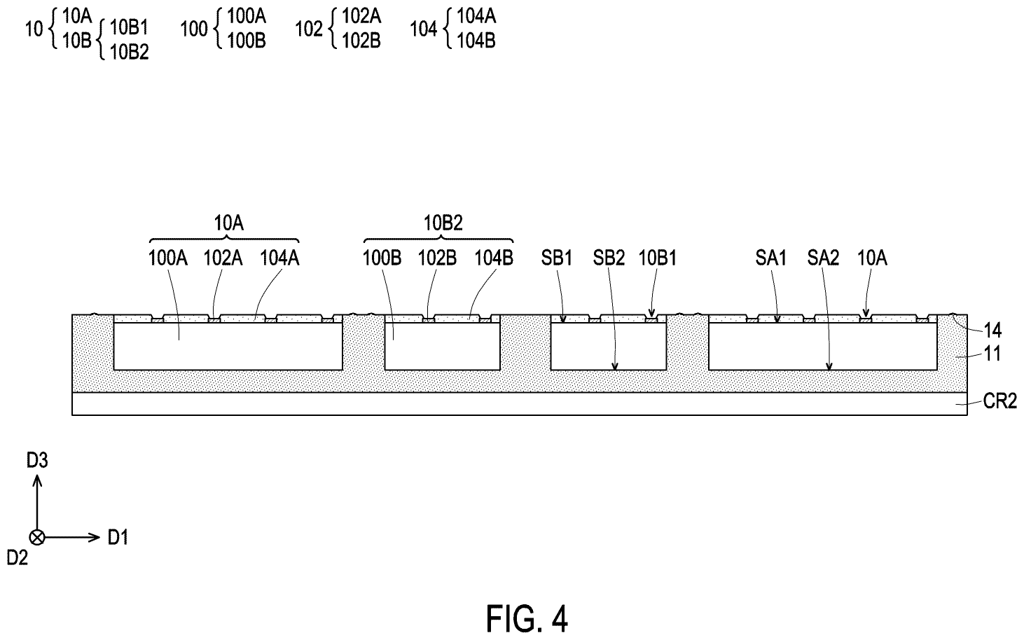

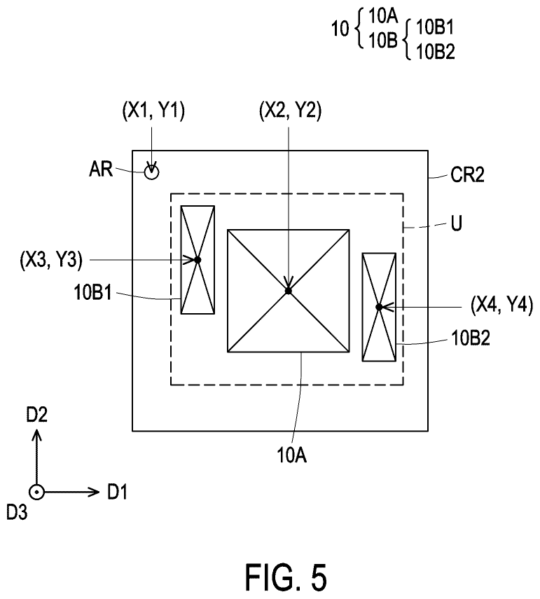

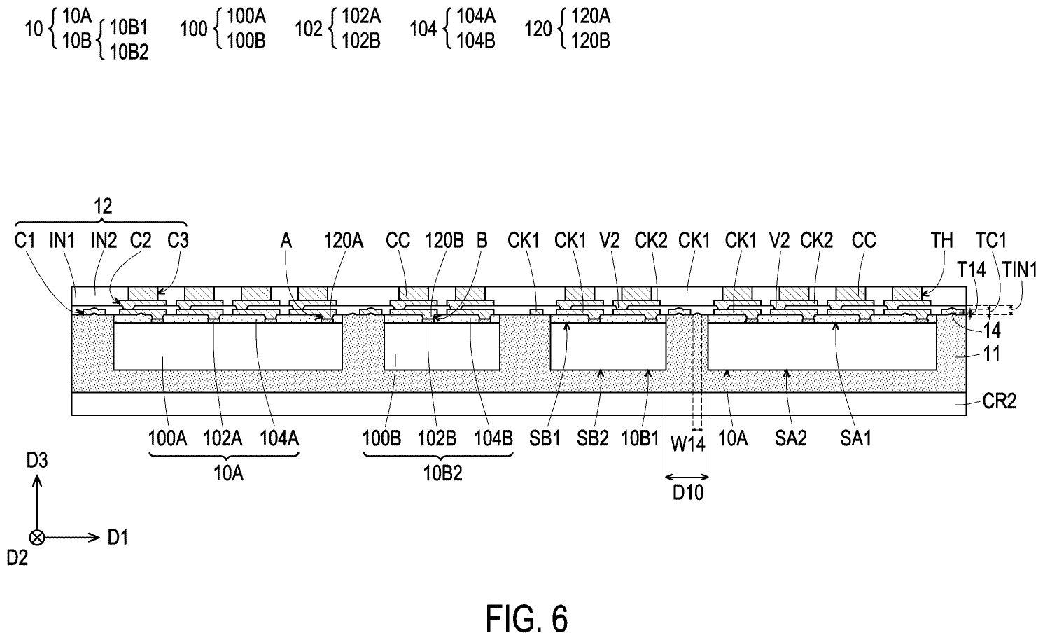

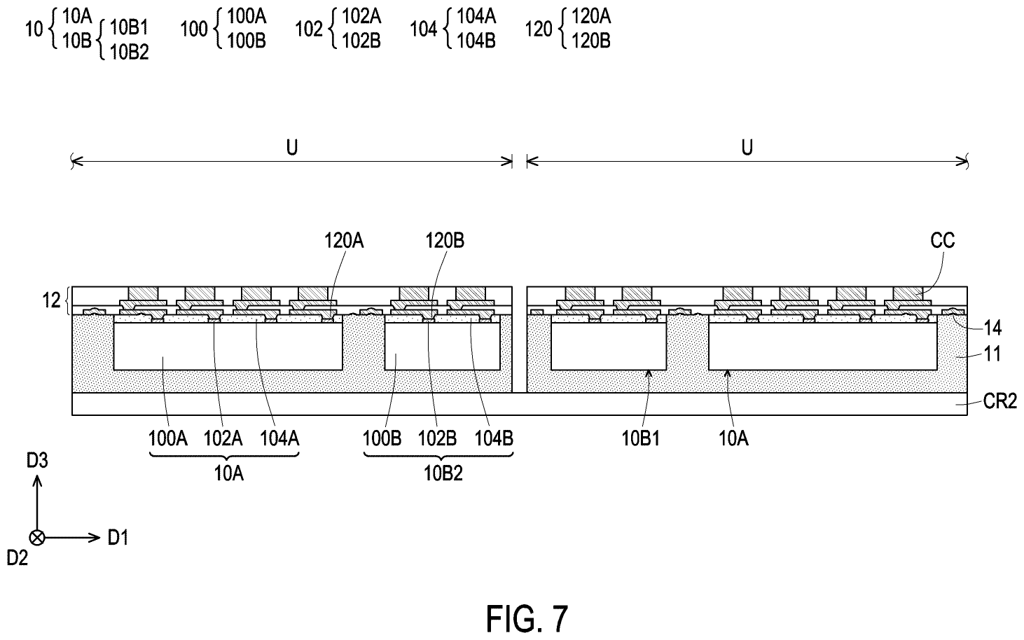

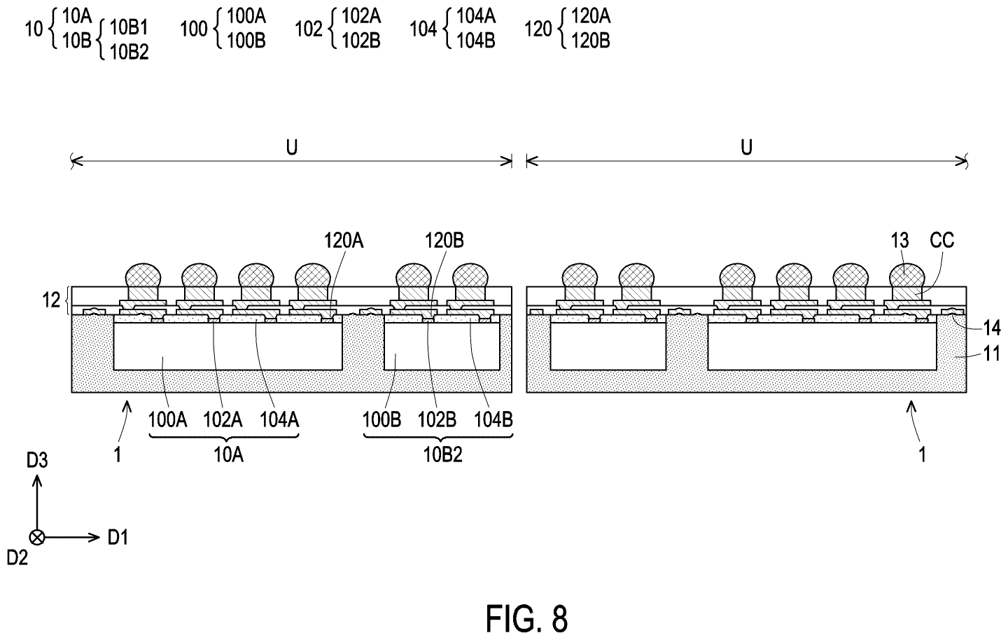

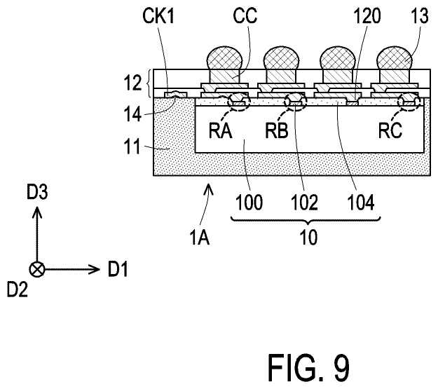

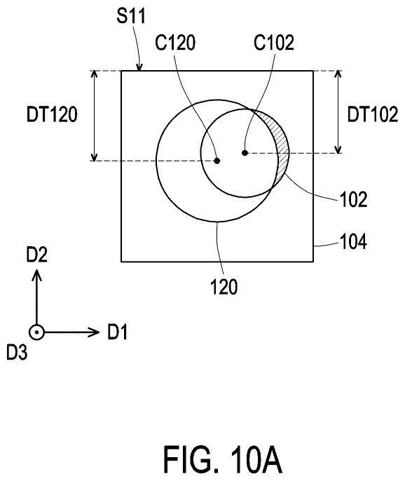

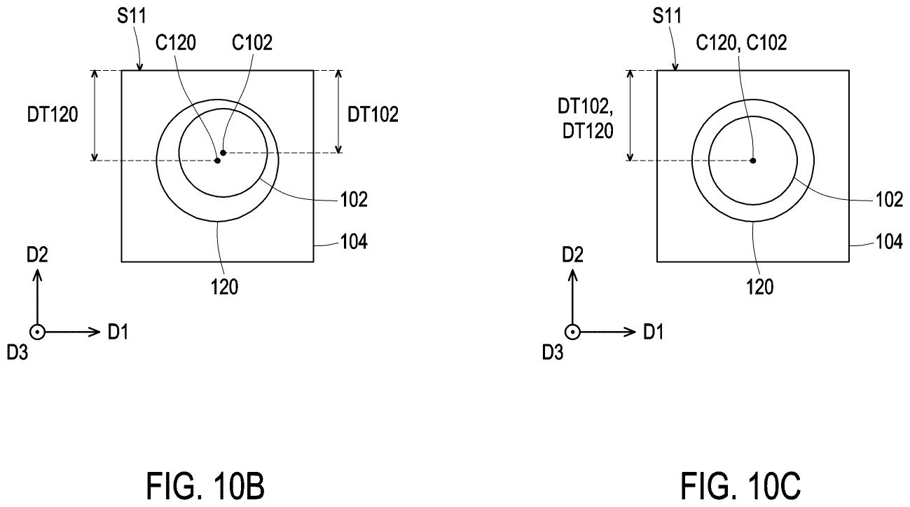

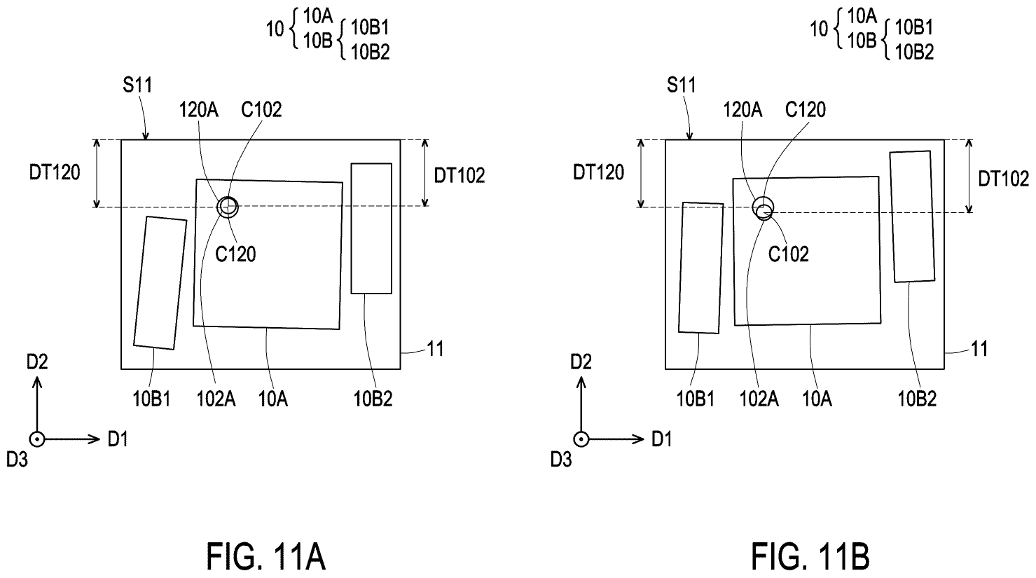

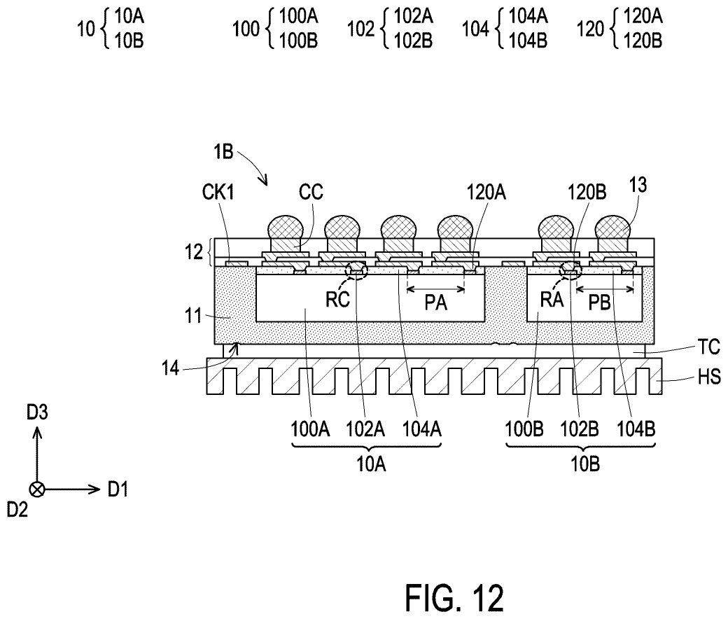

FIG. 1 is a top view illustrating the transfer of a plurality of electronic elements onto a carrier board. FIG. 2 is a schematic cross-sectional view corresponding to section line I-I′ in FIG. 1. FIG. 3 is a schematic cross-sectional view illustrating the formation of an encapsulation layer surrounding a plurality of electronic elements. FIG. 4 is a schematic cross-sectional view of a flipped carrier board. FIG. 5 is a top schematic view illustrating retrieving position information of at least one electronic element in a plurality of electronic elements and comparing the position information of the at least one electronic element with a reference value to obtain a shift amount. FIG. 6 is a schematic cross-sectional view illustrating circuit structures formed on a plurality of electronic elements and an encapsulation layer. FIG. 7 is a schematic cross-sectional view illustrating cutting a circuit structure and an encapsulation layer. FIG. 8 is a schematic cross-sectional view illustrating the formation of a bonding element on a circuit structure. FIG. 9 is a schematic cross-sectional view of an electronic device according to some embodiments of the disclosure. FIG. 10A to FIG. 10C are respectively schematic top views of the region RA, the region RB, and the region RC in FIG. 9. FIG. 11A and FIG. 11B are respectively schematic top views of two electronic devices according to some other embodiments of the disclosure. FIG. 12 is a schematic cross-sectional view of an electronic device according to some other embodiments of the disclosure. It should be noted that, in the following embodiments, without departing from the spirit of the disclosure, features in several different embodiments may be replaced, reorganized, and mixed to complete other embodiments. As long as the features of the various embodiments do not violate the spirit of the disclosure or conflict each other, they may be mixed and matched arbitrarily.

FIG. 1 to FIG. 8 are flowcharts of a manufacturing method of an electronic device according to some embodiments of the disclosure. According to some embodiments, a manufacturing method of an electronic device may include transferring a plurality of electronic elements 10 onto a carrier board CR1 (as shown in FIG. 1 and FIG. 2); forming an encapsulation layer 11 surrounding the plurality of electronic elements 10 (as shown in FIG. 3 and FIG. 4); retrieving position information of at least one electronic element in the plurality of electronic elements 10 (as shown in FIG. 5); comparing the position information of the at least one electronic element with a reference value to obtain a shift amount (as shown in FIG. 5); and forming a circuit structure 12 on the plurality of electronic elements 10 and the encapsulation layer 11, wherein the circuit structure 12 includes a plurality of contact portions 120 in contact with a plurality of pads 102 of the plurality of electronic elements 10, and a position of each of the plurality of contact portions 120 is compensated according to the shift amount, such that at least one in the plurality of contact portions 120 is aligned with at least one corresponding pad 102 (as shown in FIG. 6).

Specifically, referring to FIG. 1 and FIG. 2, the plurality of electronic elements 10 may be transferred onto the carrier board CR1 via a pick and place (PnP) process, for example. In some embodiments, an adhesive layer or a release layer (not shown) may be formed on the carrier board CR1 first, and then the plurality of electronic elements 10 are transferred onto the carrier board CR1, such that the plurality of electronic elements 10 may be temporarily fixed on the carrier board CR1 via the adhesive layer or the release layer. The adhesive layer or the release layer may lose viscosity by being heated or illuminated, such that the plurality of electronic elements 10 may be separated from the carrier board CR1.

In some embodiments, the plurality of electronic elements 10 may be transferred onto the carrier board CR1 via a plurality of pick-and-place processes. In some embodiments, the plurality of electronic elements 10 may include a plurality of electronic elements with different design parameters such as usage, size, type, shape, number of pads, and/or pad pitch. For example, transferring the plurality of electronic elements 10 onto the carrier board CR1 may include transferring a plurality of first electronic elements 10A and a plurality of second electronic elements 10B onto the carrier board CR1, wherein for example, the first electronic elements 10A have a greater number of pads than the second electronic elements 10B or have a smaller pad pitch P than the second electronic elements 10B. The pad pitch P may be the distance (for example, the distance between the two right sides of two adjacent pads or the distance between the two left sides of two adjacent pads) between two corresponding sides of two adjacent pads or the distance between two center lines of two adjacent pads. As an example, in FIG. 2, the pad pitch P is marked as the distance between two right sides of two adjacent pads.

Taking FIG. 2 as an example, each of the electronic elements 10 may include a chip 100, a pad 102, and a buffer layer 104, wherein the pad 102 is disposed on the chip 100, and the buffer layer 104 is disposed on the chip 100 and has an opening (such as an opening A or an opening B) exposing the pad 102. In this article, the placement of one element on another element describes the relative arrangement relationship between the two elements, but does not limit the process steps or sequence of the two elements.

In FIG. 2, the first electronic elements 10A include a first chip 100A, a first pad 102A, and a first buffer layer 104A, wherein the first pad 102A is disposed on the first chip 100A, and the first buffer layer 104A is disposed on the first chip 100A and has the opening A exposing the first pad 102A. In other words, the chip 100A includes a semiconductor structure, and the pad 102A may be an I/O pad. In some embodiments, the first electronic elements 10A may include a plurality of first pads 102A, and the first buffer layer 104A may have a plurality of openings A respectively exposing the plurality of first pads 102A. In the plurality of surfaces of the first chip 100A, the surface on which the first pad 102A is disposed is an active surface SA1 of the first chip 100A, and the surface opposite to the active surface SA1 is a back surface SA2 of the first chip 100A. The second electronic elements 10B include a second chip 100B, a second pad 102B, and a second buffer layer 104B, wherein the second pad 102B is disposed on the second chip 100B, and the second buffer layer 104B is disposed on the second chip 100B and has the opening B exposing the second pad 102B. In other words, the chip 100B includes a semiconductor structure, and the pad 102A may be an I/O pad. In some embodiments, the second electronic elements 10B may include a plurality of second pads 102B, and the second buffer layer 104B may have a plurality of openings B respectively exposing the plurality of second pads 102B. In the plurality of surfaces of the second chip 100B, the surface on which the second pad 102B is disposed is an active surface SB1 of the second chip 100B, and the surface opposite to the active surface SB1 is a back surface SB2 of the second chip 100B.

In FIG. 2, the plurality of electronic elements 10 (such as the plurality of first electronic elements 10A and the plurality of second electronic elements 10B) are disposed on the carrier board CR1 with the active surfaces (such as the active surface SA1 and the active surface SB1) facing downward, such that the active surfaces (such as the active surface SA1 and the active surface SB1) of the plurality of chips 100 (such as a plurality of the first chip 100A and a plurality of the second chip 100B) are located between the back surfaces (such as the back surface SA2 and the back surface SB2) and the carrier board CR1. This process method may be called a face down process, but the disclosure is not limited thereto. In other embodiments, although not shown, the plurality of electronic elements 10 may be disposed on the carrier board CR1 with the active surfaces facing upward, such that the back surfaces of the plurality of chips 100 are located between the active surfaces and the carrier board CR1. This process method may be called a face up process.

The first electronic elements 10A having a greater number of pads than the second electronic elements 10B means, for example, the total number of the first pads 102A in at least one of the plurality of first electronic elements 10A is greater than the total number of the second pads 102B in at least one of the plurality of second electronic elements 10B. The first electronic elements 10A having a smaller pad pitch than the second electronic elements 10B means, for example, the pitch PA between the plurality of first pads 102A in at least one of the plurality of first electronic elements 10A is smaller than the pitch PB between the plurality of second pads 102B in at least one of the plurality of second electronic elements 10B. The pitch between a plurality of pads may be the pitch of two adjacent pads in a direction D1, the pitch of two adjacent pads in a direction D2, or the pitch of two adjacent pads in the direction D1 and the direction D2. As an example, the pitch PA in FIG. 2 indicates the pitch of two adjacent first pads 102A in the direction D1, and the pitch PB indicates the pitch of two adjacent second pads 102B in the direction D1. In an architecture in which the plurality of first electronic elements 10A have a greater number of pads than the plurality of second electronic elements 10B or have a smaller pad pitch than the plurality of second electronic elements 10B, the requirements of the plurality of first electronic elements 10A for alignment accuracy are higher.

In some embodiments, the first chip 100A and the second chip 100B may be digital chips, analog chips, mixed-signal chips, logic chips, sensor chips, semiconductor-related process structures, or semiconductor-related process structures disposed on a substrate (such as polyimide, glass, silicon substrate, or other suitable substrate materials) or other types of integrated circuit chips or a combination thereof. For example, the first chip 100A may be a system-on-chip (SoC), and the second chip 100B may be a high bandwidth memory (HBM), but the disclosure is not limited thereto. The material of the first buffer layer 104A and the second buffer layer 104B includes, for example, an inorganic insulating material, an organic insulating material, or a combination thereof, but the disclosure is not limited thereto. The inorganic insulating material includes, for example, silicon oxide, silicon nitride, nitride, oxide, or a combination thereof, but the disclosure is not limited thereto. The organic insulating material includes, for example, photosensitive polyimide (PSPI), polyimide, epoxy, polymer, or a combination thereof, but the disclosure is not limited thereto. In some embodiments, the buffer layer may be a multi-layer stack. Specifically, along a direction D3, at least one inorganic insulating material may be first formed on the chip, then at least one organic insulating material is formed on the inorganic insulating material, such that the inorganic insulating material is disposed between the chip and the organic insulating material, or, a portion of the inorganic insulating material is disposed between the pad and the organic insulating material. In some embodiments, the material of the first buffer layer 104A and the second buffer layer 104B may further include a filler, and the particle size of the filler may be 0.05 μm to 10 μm (0.05 μm≤filler particle size≤10 μm), but the disclosure is not limited thereto. The coefficient of thermal expansion (CTE) of the first buffer layer 104A and the second buffer layer 104B is, for example, 1 ppm/° C. to 50 ppm/° C., but the disclosure is not limited thereto. The Young's modulus of the first buffer layer 104A and the second buffer layer 104B is, for example, 3 GPa to 20 GPa, but the disclosure is not limited thereto. The tensile strength of the first buffer layer 104A and the second buffer layer 104B is, for example, 50 MPa to 110 MPa, but the disclosure is not limited thereto. The material of the first pad 102A and the second pad 102B includes, for example, a transparent conductive material or an opaque conductive material. The transparent conductive material may include metal oxide, graphene, other suitable transparent conductive materials, or a combination thereof. The metal oxide may include indium tin oxide, indium zinc oxide, aluminum tin oxide, aluminum zinc oxide, indium germanium zinc oxide, or other metal oxides. The opaque conductive material may include a metal, an alloy, or a combination thereof. The pad may be, for example, one end of a transistor (e.g., a source electrode, a gate electrode, and a drain electrode), but the disclosure is not limited thereto.

In some embodiments, the plurality of first electronic elements 10A are formed by, for example, forming the first buffer layer 104A on a wafer, and then performing a singulation process on the first buffer layer 104A and the wafer. Using the first buffer layer 104A to absorb stress during the singulation process may reduce damage to the wafer caused by the singulation process. Similarly, the plurality of second electronic elements 10B are formed by, for example, forming the second buffer layer 104B on another wafer, and then performing a singulation process on the second buffer layer 104B and the other wafer. Using the second buffer layer 104B to absorb stress during the singulation process may reduce damage to the other wafer caused by the singulation process.

In FIG. 1, each of units U may include a plurality of electronic elements. For example, each of the units U may include two electronic elements, three electronic elements, or more than three. The electronic elements may have the same function or different functions. For example, each of the units U may include one first electronic element 10A and two second electronic elements 10B. The two second electronic elements 10B (such as a second electronic element 10B1 and a second electronic element 10B2) may be respectively disposed at opposite sides of the first electronic element 10A in the direction D1. The plurality of units U may be arranged in an array along the direction D1 and the direction D2. The direction D1 and the direction D2 are intersected with each other and both perpendicular to the thickness direction of the carrier board CR1 (such as the direction D3). In some embodiments, the direction D1 and the direction D2 are perpendicular to each other, but the disclosure is not limited thereto. It should be understood that, the types of the plurality of electronic elements 10, design parameters such as the relative arrangement relationship, size, and/or shape of the plurality of electronic elements (such as the plurality of first electronic elements 10A and the plurality of second electronic elements 10B) in each of the units U all may be changed according to needs, and are not limited to what is shown in FIG. 1.

Referring to FIG. 3, after the plurality of electronic elements 10 (such as the plurality of first electronic elements 10A and the plurality of second electronic elements 10B) are transferred onto the carrier board CR1, the encapsulation layer 11 surrounding the plurality of electronic elements 10 may be formed. As used herein, the expression that one element surrounds another element means that one element is in contact with at least one side surface of the other element in a cross-sectional view. In some embodiments, such as in FIG. 3, the encapsulation layer 11 may be in contact with all side surfaces and the back surfaces (such as the back surface SA2 and the back surface SB2) of each of the electronic elements 10, but the disclosure is not limited thereto. The encapsulation layer 11 may reduce the impact of moisture on the electronic devices, but the disclosure is not limited thereto. The encapsulation material of the encapsulation layer 11 includes, for example, a molding compound, a resin (e.g., an epoxy resin), a polymer, or a combination thereof, but the disclosure is not limited thereto. In some embodiments, although not shown, the encapsulation layer 11 may be thinned via a planarization process. The planarization process may include a mechanical grinding process, a chemical mechanical polishing (CMP) process, or a combination of the above.

In some embodiments, as shown in FIG. 2, before the encapsulation layer 11 is formed, a surface SCR1 of the carrier board CR1 carrying the plurality of electronic elements 10 may be optionally formed with one or a plurality of recesses R embedded into the surface SCR1. When the packaging material is formed on the carrier board CR1, as shown in FIG. 3, the packaging material may be filled into one or a plurality of recesses R, such that when the encapsulation layer 11 is formed, one or a plurality of bolts 14 may be formed together. In other words, the bolt 14 and the encapsulation layer 11 may have the same material, and the bolt 14 and the encapsulation layer 11 may be integrally formed, but the disclosure is not limited thereto. In some embodiments, a ratio of a coefficient of thermal expansion of the bolt 14 and a coefficient of thermal expansion of the encapsulation layer 11 is in a range from 0.8 to 1.1, wherein the coefficient of thermal expansion of the encapsulation layer 11 is in a range from 5-30 ppm/° C. In some embodiments, the bolt 14 may also be formed on the buffer layer 104 of at least one of the plurality of electronic elements 10. For example, as shown in FIG. 6, the bolt 14 may also be formed on the first buffer layer 104A of the first electronic element 10A. In some embodiments, the bolt 14 is overlapped with the first chip 100A along the direction D3 and not overlapped with the first pads 102A along the direction D3. In some embodiments, a distance between the bolt 14 and an edge of the first electronic element 10A close to the bolt 14 is less than or equal to 300 μm. In some of the embodiments, the bolt 14 can be omitted.

Please refer to FIG. 4. After the encapsulation layer 11 is formed, the above structure may be turned over onto another carrier board CR2, and the carrier board CR1 may be separated from the above structure. For example, the carrier board CR1 may be separated from the above structure by heating or illuminating the release layer on the carrier board CR1 to make the release layer on the carrier board CR1 lose viscosity. After the above structure is flipped onto another carrier board CR2, the plurality of pads 102 of the plurality of electronic elements 10 face upward to facilitate a subsequent process. In some embodiments, another release layer (not shown) may be formed on the carrier board CR2 first, and then the above structure is flipped onto the carrier board CR2 such that the encapsulation layer 11 may be temporarily fixed on the carrier board CR2 via another release layer. The other release layer may lose viscosity by being heated or illuminated, such that the encapsulation layer 11 may be separated from the carrier board CR2.

In some other embodiments, although not shown, if the plurality of electronic elements 10 are disposed on the carrier board CR1 with the active surface facing up, the step of FIG. 4 may be omitted, and in the step of forming the encapsulation layer 11, the packaging material covering the plurality of pads 102 (such as the plurality of first pads 102A and the plurality of second pads 102B) may be removed via a planarization process or other patterning processes. Optionally, in the step of removing the packaging material, one or a plurality of bolts 14 may be formed via a patterning process, but the disclosure is not limited thereto.

Referring to FIG. 5, after the encapsulation layer 11 is formed and before the circuit structure 12 (refer to FIG. 6) is formed, the shift amount of the electronic element may be detected first. Specifically, the position information of at least one electronic element in the plurality of electronic elements 10 may be first retrieved, and then the position information of the at least one electronic element may be compared with a reference value to obtain the shift amount. The reference value may be position information of at least one position comparison reference (such as an alignment pattern), the position information of at least one electronic element and at least one position comparison reference may be retrieved via, for example, an automated optical inspection (AOI) system or other image capture devices, and the shift amount is then obtained by comparing the two position information.

In some embodiments, retrieving the position information of the at least one electronic element includes, for example, retrieving the position information of the center of the at least one electronic element, retrieving the position information of at least one pad of the at least one electronic element, or retrieving the position information of the alignment pattern (not shown) of the at least one electronic element. The center of the electronic element 10 is the intersection of the two diagonal lines of the electronic element 10 in the top view, as shown in FIG. 5, the first electronic element 10A, the second electronic element 10B1, or the second electronic element 10B2. The alignment pattern of the electronic element 10 may be any line segment or mark in the electronic element 10 facilitating image recognition.

In some embodiments, comparing the position information of the at least one electronic element with the reference value includes, for example, comparing the position information of the at least one electronic element with the position information of the position comparison reference. The position information of the position comparison reference may be the position information of the alignment pattern on the carrier board, the position information of the bolt 14, or the position information of any pattern on the carrier board. In some embodiments, the height of the bolt 14 along the direction D3 is between 5 μm and 15 μm, and a width of the bolt 14 along the direction D1 is between 100 μm and 300 μm. According to above design, it is conducive to identification and alignment during the manufacturing process, but the disclosure is not limited thereto.

The monitoring method may capture the position information of at least one electronic element 10 on the carrier board CR2. For example, if the total number of the electronic elements 10 on the carrier board CR2 is N, then the position information of an M number of electronic elements may be detected, wherein M is a positive integer less than N. Via the above method, the shift amount detection time may be shortened and the production capacity may be improved without affecting electrical performance, but the disclosure is not limited thereto.

The method proposed by the disclosure includes: detecting at least the shift amount of at least one electronic element of one unit U, as detailed below. If the position information of a single electronic element 10 in one unit U is obtained for shift amount detection, the position information of the electronic element needing higher positioning accuracy (such as the first electronic element 10A having a larger number of pads or a smaller pad pitch) may be used to perform shift amount detection. For example, the center position information of the first electronic element 10A may be retrieved, the position information of at least one first pad 102A of the first electronic element 10A may be retrieved, or the position information of the alignment pattern of the first electronic element 10A may be retrieved, and then the position information is compared with the position information of a position comparison reference (such as an alignment pattern AR on the carrier board CR2 or the bolt 14 of FIG. 4) to obtain the shift amount. Then, the shift amount may be provided to a machine (not shown) manufacturing the circuit structure 12 (see FIG. 6), such that the machine may calculate an appropriate compensation value according to the shift amount, and according to the shift amount, compensate the position of each of the plurality of contact portions 120 (such as the plurality of first contact portions 120A and the plurality of second contact portions 120B shown in FIG. 6) in contact with the plurality of pads 102 (such as the plurality of first pads 102A and the plurality of second pads 102B). The machine may include, for example, a mask exposure machine, a maskless exposure machine, a laser machine, or any machine equipment needed in the electronic element manufacturing process.

The method proposed by the disclosure includes: detecting at least the shift amount of at least one electronic element of one unit U, as detailed below. If the position information of more than one electronic element 10 in one unit U is used for shift amount detection, a plurality of electronic elements 10 of the same type may be used. For example, the position information of two or more first electronic elements 10A or the position information of two or more second electronic elements 10B is used to perform shift amount detection. Alternatively, a plurality of electronic elements 10 of different types, such as the position information of at least one first electronic element 10A and the position information of at least one second electronic element 10B may be used to perform shift amount detection.

If the position information of the plurality of electronic elements 10 of the same type is used for shift amount detection, a plurality of electronic elements needing higher positioning accuracy may be used. For example, shift amount detection is performed according to the position information of the plurality of first electronic elements 10A having a larger number of pads or a smaller pad pitch. For example, an M number of center position information of an M number of first electronic elements 10A may be retrieved, the position information of at least one first pad 102A of each of the M number of first electronic elements 10A may be retrieved, or the position information of a plurality of alignment patterns (not shown) of the M number of first electronic elements 10A may be retrieved, and then the position information is compared with the position information of a position comparison reference (such as the alignment pattern AR on the carrier board CR2 or the bolt 14 of FIG. 4) to obtain a plurality of shift amounts. At this time, the plurality of shift amounts may be averaged, and then the average shift amount is provided to the machine manufacturing the circuit structure 12, such that the machine compensates the position of each of the plurality of contact portions 120 in contact with the plurality of pads 102 according to the shift amount, thereby providing a qualified circuit structure 12. The electrical quality of the electronic device may be improved via the above method, but the disclosure is not limited thereto. Specifically, after the machine receives the shift amount, the shift amount may be compared with the standard position and then the position of the circuit structure may be compensated such that the resulting circuit structure may be electrically connected to the electronic elements.

If the position information of the plurality of electronic elements 10 of different types is obtained for shift amount detection, the unit U may be used as the unit to retrieve the position information of at least one first electronic element 10A and at least one second electronic element 10B in the at least one unit U to perform shift amount detection. FIG. 5 schematically illustrates capturing the position information of all of the electronic elements 10 in one unit U and the position information of the alignment pattern AR on the carrier board CR2, and comparing the position information to obtain the shift amount. The position information may include coordinates on the plane where the direction D1 and the direction D2 are located. In FIG. 5, coordinates (X1, Y1) represent the position information of the alignment pattern AR, and coordinates (X2, Y2) represent the position information of the center of the first electronic element 10A, and the coordinates (X3, Y3) and the coordinates (X4, Y4) represent the position information of the centers of the second electronic element 10B1 and the second electronic element 10B2 respectively.

In some embodiments, the shift amount of the first electronic element 10A (for example, referred to as the first shift amount) may be confirmed by comparing the coordinates (X1, Y1) and the coordinates (X2, Y2). In some embodiments, the shift amount of the second electronic element 10B1 (for example, referred to as the second shift amount) may be confirmed by comparing the coordinates (X2, Y2) and the coordinates (X3, Y3) or comparing the coordinates (X1, Y1) and the coordinates (X3, Y3). Similarly, the shift amount of the second electronic element 10B2 (for example, also referred to as the second shift amount) may be confirmed by comparing the coordinates (X2, Y2) and the coordinates (X4, Y4) or comparing the coordinates (X1, Y1) and the coordinates (X4, Y4).

Next, the shift amount of the first electronic element 10A, the shift amount of the second electronic element 10B1, and the shift amount of the second electronic element 10B2 may be provided to a machine (not shown) for manufacturing the circuit structure 12 (see FIG. 6), such that the machine calculates three compensation values according to the shift amounts, wherein the position of each of the plurality of first contact portions 120A in contact with the plurality of first pads 102A of the plurality of first electronic elements 10A may be compensated according to the shift amount of the first electronic elements 10A, the position of each of the plurality of second contact portions 120B in contact with the plurality of second pads 102B of the plurality of second electronic elements 10B1 (for example, the second electronic element located at the left side of the first electronic element 10A in the plurality of units U) may be compensated according to the shift amount of the second electronic elements 10B1, and the position of each of the plurality of second contact portions 120B in contact with the plurality of second pads 102B of the plurality of second electronic elements 10B2 (for example, the second electronic element located at the right side of the first electronic element 10A in the plurality of units U) may be compensated according to the shift amount of the second electronic elements 10B2.

Alternatively, the shift amount detection of at least one second electronic element 10B in the unit U may be omitted. For example, shift amount detection may be performed for the second electronic element 10B1 or the second electronic element 10B2 in one or more (i.e., greater than or equal to one) unit U, and the position of each of the plurality of second contact portions 120B in contact with the plurality of second pads 102B of the plurality of second electronic elements 10B (such as the plurality of second electronic elements 10B1 and the plurality of second electronic elements 10B2) may be compensated according to the resulting shift amount to further simplify shift amount detection or shorten the time of shift amount detection.

That is, in the manufacturing method of the electronic device, retrieving the position information of the at least one electronic element 10 may at least include retrieving the position information of at least one first electronic element 10A in the plurality of first electronic elements 10A, and comparing the position information of the at least one electronic element 10 with the reference value may at least include comparing the position information of the at least one first electronic element 10A with a position comparison reference to obtain the first shift amount of the shift amount. Furthermore, as shown in FIG. 6, in the circuit structure 12, the plurality of contact portions 120 may include the plurality of first contact portions 120A in contact with the plurality of first pads 102A of the plurality of first electronic elements 10A and the plurality of second contact portions 120B in contact with the plurality of second pads 102B of the plurality of second electronic elements 10B, and the position of each of the plurality of first contact portions 120A and each of the plurality of second contact portions 120B may be compensated according to the first shift amount.

Alternatively, in the manufacturing method of the electronic device, retrieving the position information of the at least one electronic element 10 may further include retrieving the position information of at least one second electronic element (such as at least one second electronic element 10B1 or at least one second electronic element 10B2) in the plurality of second electronic elements 10B, and comparing the position information of the at least one electronic element 10 with the reference value may also include comparing the position information of the at least one second electronic element with the position information of at least one first electronic element 10A, or comparing with the position information of the position comparison reference to obtain the second shift amount of the shift amount. As shown in FIG. 6, the plurality of contact portions 120 include the plurality of first contact portions 120A in contact with the plurality of first pads 102A of the plurality of first electronic elements 10A and the plurality of second contact portions 120B in contact with the plurality of second pads 102B of the plurality of second electronic elements 10B, the position of each of the plurality of first contact portions 120A is compensated according to the first shift amount, and the position of each of the plurality of second contact portions 120B is compensated according to the second shift amount.

By performing shift amount detection on at least one electronic element 10 and compensating the position of each of the plurality of contact portions 120 in the subsequent circuit structure 12 to be formed according to the resulting shift amount, productivity may be improved while shortening shift amount detection time, simplifying calculations, or reducing costs.

Referring to FIG. 6, after shift amount detection is performed, the circuit structure 12 may be formed on the plurality of electronic elements 10 and the encapsulation layer 11, wherein the circuit structure 12 may include the plurality of contact portions 120 in contact with the plurality of pads 102 of the plurality of electronic elements 10, and the position of each of the plurality of contact portions 120 is compensated according to the shift amount, such that at least one in the plurality of contact portions 120 is aligned with at least one corresponding pad 102. For example, at least one in the plurality of first contact portions 120A in the plurality of contact portions 120 in contact with the plurality of first pads 102A may be aligned with at least one corresponding first pad 102A, but the disclosure is not limited thereto. In some embodiments, the plurality of first contact portions 120A in the plurality of contact portions 120 in contact with the plurality of first pads 102A may be respectively aligned with the plurality of first pads 102A, and the plurality of second contact portions 120B in the plurality of contact portions 120 in contact with the plurality of second pads 102B may be respectively aligned with the plurality of second pads 102B. As used herein, alignment of an element with another element means that the center of an element is overlapped with the center of another element in the direction D3. In contrast, the misalignment between one element and another element means that the center of one element is not overlapped with the center of another element in the direction D3, or means that the overlap area of two elements is smaller than the area of the smaller of the two elements.

The circuit structure 12 may also be referred to as a redistribution structure. In some embodiments, the circuit structure 12 may include at least one insulating layer and at least one conductive layer. In FIG. 6, two insulating layers and three conductive layers are used as an example, but the circuit structure 12 may include more or less insulating layers and conductive layers according to requirements. Via the above at least one insulating layer and at least one conductive layer, the circuits may be redistributed and/or the circuit fan-out or fan-in area may be increased, or different electronic elements 10 may be electrically connected to each other via the circuit structure 12. For example, the distance between two adjacent pads of the circuit structure in contact with one end of the chip may be less than or equal to the distance between two adjacent pads of the circuit structure far away from one end of the chip. Therefore, the circuit fan-out condition of the circuit structure may be adjusted, but the disclosure is not limited thereto. The method of forming the circuit structure 12 may include using a photolithography process, a surface treatment process, a laser process, an electroplating process, a deposition process, or other processes to form at least one insulating layer and at least one conductive layer. The surface treatment process includes roughening the surface of the insulating layer or the surface of the conductive layer to improve the bonding ability thereof.

Surface roughness may be measured using a scanning electron microscope (SEM), a transmission electron microscope (TEM), etc. to observe the surface undulations at the same appropriate magnification and compare the undulations per unit length (for example, 10 μm). Appropriate magnification means that at least 10 undulating peaks may be seen at least one surface under the field of view at this magnification. In some embodiments, the surface treatment process may be used to make the peaks and valleys of the surface undulations of the insulating layer or the conductive layer have a height difference of 0.15 μm to 3 μm. For example, the peaks and valleys of the surface undulations of the conductive layer C3 may have a height difference of 0.15 μm to 3 μm to improve the bonding ability thereof.

As shown in FIG. 6, the circuit structure 12 may include a conductive layer C1, an insulating layer IN1, a conductive layer C2, an insulating layer IN2, and a conductive layer C3, but the disclosure is not limited thereto. Each of the conductive layer C1, the conductive layer C2, and the conductive layer C3 may be a single conductive layer or a conductive stack. In addition, the material of the conductive layer C1, the conductive layer C2, and the conductive layer C3 may include a metal, an alloy, or a combination thereof. The material of the insulating layer IN1 and the insulating layer IN2 may include an organic insulating material, an inorganic insulating material, or a combination thereof. Examples of the organic insulating material include polymethylmethacrylate (PMMA), epoxy, acrylic-based resin, silicone, polyimide polymer, or a combination thereof, but the disclosure is not limited thereto. The inorganic insulating material includes, for example, silicon oxide or silicon nitride, but the disclosure is not limited thereto.

The conductive layer C1 may be a patterned conductive layer and may include a plurality of circuits CK1 and the plurality of contact portions 120. The plurality of circuits CK1 may be disposed on the plurality of chips 100A/100B, the encapsulation layer 11, and the plurality of bolts 14. Each of the contact portions 120 may be extended from a corresponding circuit CK1 to the opening A or the opening B and be in contact with one corresponding pad 102.

The insulating layer IN1 is disposed on the conductive layer C1, the plurality of chips 100A/100B, the encapsulation layer 11, and the plurality of bolts 14. The conductive layer C2 is disposed on the insulating layer IN1. The conductive layer C2 may be a patterned conductive layer and may include a plurality of circuits CK2 and a plurality of conductive vias V2. The plurality of circuits CK2 may be disposed on the insulating layer IN1. Each of the conductive vias V2 may penetrate the insulating layer IN1 from a corresponding circuit CK2 and be electrically connected to a corresponding circuit CK1.

The insulating layer IN2 is disposed on the conductive layer C2 and the insulating layer IN1 and includes a plurality of through holes TH. Each of the through holes TH exposes a local region of a corresponding circuit CK2. The conductive layer C3 may be a patterned conductive layer and may include a plurality of conductive pillars CC. Each of the conductive pillars CC is disposed in one corresponding through hole TH and in contact with a local region of a corresponding circuit CK2.

As shown in FIG. 6, the plurality of bolts 14 may be disposed between the encapsulation layer 11 and the circuit structure 12. In some embodiments, a thickness T14 of the bolts 14 is, for example, smaller than a thickness TIN1 of the insulating layer IN1 and a thickness TC1 of the conductive layer C1. Specifically, in the same cross-sectional view, the maximum thickness T14 of the bolts 14 is less than or equal to half of the maximum thickness of the insulation layer IN1 (T14≤1/2*TIN1), or the maximum thickness T14 of the bolts 14 is less than or equal to one third of the maximum thickness of the insulating layer IN1 (T14≤1/3*TIN1), and the maximum thickness T14 of the bolts 14 is less than or equal to half of the maximum thickness TC1 of the conductive layer C1 (T14≤1/2*TC1), or the maximum thickness T14 of the bolts 14 is less than or equal to one third of the maximum thickness TC1 of the conductive layer C1 (T14≤1/3*TC1), in order to reduce the probability that the plurality of circuits CK1 are disconnected due to the bolts 14. In some embodiments, as shown in FIG. 6, the number of the electronic elements 10 surrounded by the encapsulation layer 11 may be a plurality, and a width W14 of the bolts 14 may be smaller than a distance D10 between two adjacent ones of the plurality of electronic elements 10. Using the bolts 14 to fit the encapsulation layer 11 and the circuit structure 12 into each other helps to alleviate the peeling issue caused by the opposite warping directions of the encapsulation layer 11 and the circuit structure 12 in a subsequent process.

Referring to FIG. 7, in some embodiments, the manufacturing method of the electronic device may further include cutting the encapsulation layer 11 and the circuit structure 12 to separate the plurality of units U from each other. The cutting tool may include a laser or a knife, but the disclosure is not limited thereto.

Referring to FIG. 8, in some embodiments, the manufacturing method of the electronic device may further include forming a plurality of bonding elements 13 on the circuit structure 12, wherein for example, the plurality of bonding elements 13 are electrically connected to the plurality of conductive pillars CC in the circuit structure 12 respectively. In some embodiments, the manufacturing method of the electronic device may also include performing a heating or illumination process on the release layer (not shown) on the carrier board CR2 to cause the release layer on the carrier board CR2 to lose viscosity so as to separate the carrier board CR2 from the encapsulation layer 11. In this way, the manufacture of an electronic device 1 may be initially completed.

It should be understood that, the steps shown in FIG. 1 to FIG. 8 are examples. The manufacturing method of an electronic device may add or delete one or a plurality of steps in the above steps, or may improve the above steps.

In some embodiments, as shown in FIG. 9, an electronic device 1A may include the electronic element 10, the encapsulation layer 11, the circuit structure 12, the bonding element 13, and the bolt 14. The encapsulation layer 11 surrounds the electronic element 10. The circuit structure 12 is electrically connected to the electronic element 10. The bonding element 13 is electrically connected to the electronic element 10 via the circuit structure 12. The bolt 14 is disposed between the circuit structure 12 and the encapsulation layer 11.

In the electronic device 1A, the contact portion 120 of the circuit structure 12 in contact with the pad 102 may be misaligned with the pad 102. In some embodiments, as shown in FIG. 9, in the same cross-sectional view, the number of the pad 102 of the electronic element 10 may be a plurality, and the circuit structure 12 may include a plurality of contact portions 120 overlapped with the plurality of pads 102, wherein the degree of overlap between the plurality of contact portions 120 and the plurality of pads 102 may be different. For example, the electronic element 10 may include the first pad 102A and a first pad 102A′ (not labeled), the circuit structure 12 may include the first contact portion 120A and a first contact portion 120A′ (not labeled), the first contact portion 120A is overlapped with the first pad 102A, the first contact portion 120A′ is overlapped with the first pad 102A′, then, the degree to which the first contact portion 120A is overlapped with the first pad 102A may be different from the degree to which the first contact portion 120A′ is overlapped with the first pad 102A′. The situations where the degree of overlap is different include: (1) the overlap area is the same, but the distance between the center of the pad and the center of the contact portion is different; and (2) the overlap area is different. In some embodiments, the area ratio of the plurality of pads 102 completely overlapped with the plurality of contact portions 120 may be greater than or equal to 70% to achieve good electrical performance. In this article, complete overlap of two elements means that the centers of the two elements are overlapped or aligned in the direction D3. FIG. 10A illustrates an example in which the pad 102 and the contact portion 120 are misaligned or not completely overlapped. In FIG. 10A, a center C102 of the pad 102 and a center C120 of the contact portion 120 are not overlapped in the direction D3, and in a top view, the overlap area of the pad 102 and the contact portion 120 is smaller than the area of the pad 102. For example, the orthographic projection of the pad 102 on the encapsulation layer 11 does not completely fall within the orthographic projection of the contact portion 120 on the encapsulation layer 11, and a portion of the orthographic projection of the pad 102 on the encapsulation layer 11 is protruded beyond the orthographic projection of the contact portion 120 on the encapsulation layer 11.

FIG. 10B illustrates another example in which the pad 102 and the contact portion 120 are misaligned or not completely overlapped. In FIG. 10B, the center C102 of the pad 102 and the center C120 of the contact portion 120 are not overlapped in the direction D3, but in a top view, the orthographic projection of the pad 102 on the encapsulation layer 11 completely falls within the orthographic projection of the contact portion 120 on the encapsulation layer 11.

FIG. 10C illustrates an example in which the pad 102 and the contact portion 120 are aligned or completely overlapped. In FIG. 10C, the center C102 of the pad 102 is overlapped with the center C120 of the contact portion 120 in the direction D3.

The different overlap degrees of the plurality of contact portions 120 and the plurality of pads 102 may mean that the plurality of contact portions 120 and the plurality of pads 102 have various different overlap areas. For example, the overlap area of the contact portion 120 and the pad 102 in FIG. 10A is smaller than the overlap area of the contact portion 120 and the pad 102 in FIG. 10B or FIG. 10C. When the pad 102 and the contact portion 120 are misaligned or not completely overlapped, the overlap area of the pad 102 and the contact portion 120 is, for example, 70% or more of the area of the pad 102 to achieve good electrical performance. Specifically, the area referred to in the disclosure refers to, in a projection direction (such as the direction D3), the pad 102 exposed by the buffer layer 104 has an area A, and the contact portion 120 of the contact pad 102 has an area B, wherein (B—the area of the contact portion 120 not overlapped with the pad 102 (for example, the hatched portion in FIG. 10A))/A*100≥70% may maintain good electrical performance, and the area of the contact portion 120 is the bottom area. That is, the area of the contact portion 120 may be the area of the portion directly in contact with the pad 102. According to some embodiments, the area of the pad 102 is almost equal to the bottom area of the contact portion 120. For convenience of description, circles with different sizes are used in the illustration.

Alternatively, the above different overlap degrees of the plurality of contact portions 120 and the plurality of pads 102 may mean that the plurality of contact portions 120 and the plurality of pads 102 have different degrees of center shift amount. The center shift amount refers to the shift amount between the center C102 of the pad 102 and the center C120 of the contact portion 120. For example, in FIG. 10A, the shift amount between the center C102 of the pad 102 and the center C120 of the contact portion 120 is greater than the shift amount between the center C102 of the pad 102 and the center C120 of the contact portion 120 in FIG. 10B, and the center shift amount in FIG. 10B is greater than the shift amount between the center C102 of the pad 102 and the center C120 of the contact portion 120 in FIG. 10C.

In the electronic device 1A, the positions of the plurality of pads 102 of the same electronic element 10 may be shifted due to factors such as manufacturing process deviations or thermal expansion and contraction. As a result, a distance DT102 between the center C102 of the plurality of pads 102 adjacent to an edge S11 of the encapsulation layer 11 and the edge S11 is different, as shown in FIG. 10A to FIG. 10C. Moreover, since the positions of the plurality of contact portions 120 corresponding to the same electronic element 10 are compensated according to the same deviation value (refer to the above), a distance DT120 between the center C120 of the plurality of contact portions 120 adjacent to the edge S11 of the encapsulation layer 11 and the edge S11 is the same, as shown in FIG. 10A to FIG. 10C.

In FIG. 9, using the bolt 14 to fit the encapsulation layer 11 and the circuit structure 12 into each other helps to alleviate the peeling issue caused by the opposite warping directions of the encapsulation layer 11 and the circuit structure 12. However, in some other embodiments, although not shown in FIG. 9, the electronic device 1A may not include the bolt 14. For example, the bolt 14 may be removed in the above step of cutting the encapsulation layer 11 and the circuit structure 12 (as shown in FIG. 7), but the disclosure is not limited thereto. In this way, the electronic device 1A includes the electronic element 10, the encapsulation layer 11, and the circuit structure 12. The encapsulation layer 11 surrounds the electronic element 10. The circuit structure 12 is electrically connected to the electronic element 10. The electronic element 10 includes the plurality of pads 102, and the circuit structure 12 includes the plurality of contact portions 120 respectively overlapped with the plurality of pads 102. One contact portion 120 of the plurality of contact portions 120 may be aligned with one corresponding pad 102 (as shown in FIG. 10C), and another contact portion 120 of the plurality of contact portions 120 may be misaligned from another corresponding pad 102 (as shown in FIG. 10A or 10B). As mentioned above, in an architecture where the contact portion 120 is aligned with the corresponding pad 102, as shown in FIG. 10C, the overlap area of the contact portion 120 and the corresponding pad 102 may be equal to the area of the corresponding pad 102; moreover, in an architecture in which the contact portion 120 is misaligned with the corresponding pad 102, as shown in FIG. 10A, the overlap area of the contact portion 120 and the corresponding pad 102 may be 70% or more and less than 100% of the area of the corresponding pad 102, that is, the overlap area may be greater than or equal to 0.7 times the area of the pad 102 and less than or equal to the area of the pad 102.

Please refer to FIG. 11A and FIG. 11B. In FIG. 11A and FIG. 11B, in order to clearly show the relative arrangement relationship between the plurality of electronic elements, the plurality of electronic elements 10 and the encapsulation layer 11 are schematically shown, and the circuit structure 12 is omitted. In addition, to simplify the description, FIG. 11A and FIG. 11B schematically illustrate one first pad 102A and one corresponding first contact portion 120A of the first electronic element 10A.

The electronic devices shown in FIG. 11A and FIG. 11B are, for example, two packaging devices formed by the steps shown in FIG. 1 to FIG. 8. In the two electronic devices shown in FIG. 11A and FIG. 11B, the position of the pad (such as the first pad 102A) of the electronic element 10 (such as the first electronic element 10A) may be shifted due to factors such as process deviation or thermal expansion and contraction. Therefore, the distance (such as the distance DT102) between the center (such as the center C102) of the pad (such as the first pad 102A) of the same electronic element (such as the first electronic element 10A) in different electronic devices and the edge S11 of the encapsulation layer 11 is not always the same. Moreover, since the position of the contact portion (such as the first contact portion 120A) corresponding to the same electronic element (such as the first electronic element 10A) in different electronic devices is compensated according to the same deviation value (refer to the above), the distance DT120 between the center (such as the center C120) of the contact portion (such as the first contact portion 120A) and the edge S11 in different electronic devices is the same.

Referring to FIG. 12, an electronic device 1B may include a packaging structure and the circuit structure 12. The packaging structure may include the first electronic element 10A, the second electronic element 10B, and the encapsulation layer 11 surrounding the first electronic element 10A and the second electronic element 10B. The first electronic element 10A is electrically connected to the second electronic element 10B via the circuit structure 12. The circuit structure 12 includes the first contact portion 120A overlapped with the first pad 102A of the first electronic element 10A and the second contact portion 120B overlapped with the second pad 102B of the second electronic element 10A. The first contact portion 120A is aligned with the first pad 102A (e.g., with reference to the region RC), and the second contact portion 120B is misaligned with the second pad 102B (e.g., with reference to the region RA). In some embodiments, the bolts 14 and the circuit structure 12 are respectively located on opposite sides of the encapsulation layer 11. In some embodiments, the electronic device 1B may further include a thermal conductive layer TC and a heat sink HS, wherein the packaging structure is located between the circuit structure 12 and the thermal conductive layer TC, and the thermal conductive layer TC is located between the packaging structure and the heat sink HS.

In some embodiments, as shown in FIG. 10C, the overlap area of the first contact portion 120A and the first pad 102A may be equal to the area of the first pad 102A; moreover, as shown in FIG. 10A, the overlap area of the second contact portion 120B and the second pad 102B may be 70% or more and less than 100% of the area of the second pad 102B. That is, the overlap area may be greater than or equal to 0.7 times the area of the second pad 102B and less than or equal to the area of the pad 102. In some embodiments, as shown in FIG. 12, the first electronic element 10A and the second electronic element 10B may satisfy at least one in the following: the first electronic element 10A has a greater number of pads than the second electronic element 10B; and the first electronic element 10A has a smaller pad pitch than the second electronic element 10B (for example, the pitch PA is smaller than the pitch PB).

Based on the above, in an embodiment of the disclosure, by performing shift amount detection and compensating the positions of the plurality of contact portions in the circuit structure according to the resulting shift amount, the adverse effects caused by chip shift may be reduced.

The above embodiments are used to illustrate the technical solutions of the disclosure, not to limit them. Although the disclosure has been described in detail with reference to the above embodiments, those having ordinary skill in the art should understand that: it is still possible to modify the technical solutions recited in the above embodiments, or perform equivalent replacements for some or all of the technical features. However, these modifications or replacements do not make the essence of the corresponding technical solutions depart from the scope of the technical solutions of the embodiments of the disclosure.

Although the embodiments of the disclosure and the advantages thereof are disclosed above, it should be understood that, anyone having ordinary skill in the art, without departing from the spirit and scope of the disclosure, may modify substitute, and polish, and the features of each embodiment may be arbitrarily mixed and replaced with each other to form other new embodiments. Moreover, the scope of protection of the disclosure is not limited to the process, machine, manufacture, material composition, device, method, and steps in the specific embodiments described in the specification. Anyone having ordinary skill in the art may understand the current or future developed process, machine, manufacture, material composition, device, method, and steps from the content disclosed in the disclosure, which may all be used according to the disclosure as long as substantially the same function may be implemented or substantially the same result may be obtained in the embodiments described herein. Therefore, the scope of protection of the disclosure includes the above process, machine, manufacture, material composition, device, method, and steps. In addition, each claim constitutes an individual embodiment, and the scope of protection of the disclosure also includes the combination of each claim and the embodiments. The scope of protection of the disclosure should be defined by the scope of the attached claims.

What is claimed is:

1. An electronic device, comprising:
an electronic element;
an encapsulation layer surrounding the electronic element;
a circuit structure electrically connected to the electronic element;
a bonding element electrically connected to the electronic element via the circuit structure; and
a bolt disposed between the circuit structure and the encapsulation layer.

2. The electronic device of claim 1, wherein the circuit structure comprises an insulating layer and a conductive layer, and a thickness of the bolt is less than a thickness of the insulating layer and a thickness of the conductive layer.

3. The electronic device of claim 1, wherein a number of the electronic element surrounded by the encapsulation layer is a plurality, and a width of the bolt is less than a distance between two adjacent ones in the plurality of electronic elements.

4. The electronic device of claim 1, wherein the electronic element comprises:
a chip;
a pad disposed on the chip; and
a buffer layer disposed on the chip and having an opening exposing the pad.

5. The electronic device of claim 4, wherein a contact portion in the circuit structure in contact with the pad is misaligned with the pad.

6. The electronic device of claim 4, wherein the electronic element comprises at least two first pads, the circuit structure comprises at least two contact portions respectively overlapped with the at least two first pads, and a degree to which one of the at least two first pads is overlapped with one of the at least two contact portions is different from a degree to which the other one of the at least two first pads is overlapped with the other one of the at least two contact portions.

7. The electronic device of claim 6, wherein a proportion of one of the at least two first pads overlapped with one of the at least two contact portions is greater than or equal to 70%, and a proportion of the other one of the at least two first pads overlapped with the other one of the at least two contact portions is greater than or equal to 70%.

8. The electronic device of claim 1, wherein the bolt and the encapsulation layer have a same material.

9. An electronic device, comprising:
a packaging structure comprising a first electronic element, a second electronic element, and an encapsulation layer surrounding the first electronic element and the second electronic element; and
a circuit structure, wherein the first electronic element is electrically connected to the second electronic element via the circuit structure, and the circuit structure comprises a first contact portion overlapped with a first pad of the first electronic element and a second contact portion overlapped with a second pad of the second electronic element;
wherein the first contact portion is aligned with the first pad, and the second contact portion is misaligned with the second pad.

10. The electronic device of claim 9, wherein an overlap area of the first contact portion and the first pad is equal to an area of the first pad, and an overlap area of the second contact portion and the second pad is 70% or more and less than 100% of an area of the second pad.

11. The electronic device of claim 9, wherein the first electronic element and the second electronic element satisfy at least one in the following:
the first electronic element has a greater number of pads than the second electronic element; and
the first electronic element has a smaller pad pitch than the second electronic element.

12. An electronic device, comprising:
an electronic element;
an encapsulation layer surrounding the electronic element; and
a circuit structure electrically connected to the electronic element;
wherein the electronic element comprises a plurality of pads, and the circuit structure comprises a plurality of contact portions respectively overlapped with the plurality of pads;
wherein one contact portion in the plurality of contact portions is aligned with one corresponding pad, and another contact portion in the plurality of contact portions is misaligned with another corresponding pad.

13. The electronic device of claim 12, wherein an overlap area of the one contact portion and the one corresponding pad is equal to an area of the one corresponding pad, and an overlap area of the other contact portion and the other corresponding pad is 70% or more and less than 100% of an area of the other corresponding pad.

14. A manufacturing method of an electronic device, comprising:
transferring a plurality of electronic elements onto a carrier board;
forming an encapsulation layer surrounding the plurality of electronic elements;
retrieving position information of at least one electronic element in the plurality of electronic elements;
comparing the position information of the at least one electronic element with a reference value to obtain a shift amount; and
forming a circuit structure on the plurality of electronic elements and the encapsulation layer, wherein the circuit structure comprises a plurality of contact portions in contact with a plurality of pads of the plurality of electronic elements, and a position of each of the plurality of contact portions is compensated according to the shift amount, such that at least one in the plurality of contact portions is aligned with at least one corresponding pad.

15. The manufacturing method of the electronic device of claim 14, wherein retrieving the position information of the at least one electronic element comprises:
retrieving position information of a center of the at least one electronic element;
retrieving position information of at least one pad of the at least one electronic element; or
retrieving position information of an alignment pattern of the at least one electronic element.

16. The manufacturing method of the electronic device of claim 14, wherein comparing the position information of the at least one electronic element with the reference value comprises comparing the position information of the at least one electronic element with position information of a position comparison reference.

17. The manufacturing method of the electronic device of claim 14, wherein transferring the plurality of electronic elements onto the carrier board comprises transferring a plurality of first electronic elements and a plurality of second electronic elements onto the carrier board, and the plurality of first electronic elements have a greater number of pads than the plurality of second electronic elements or has a smaller pad pitch than the plurality of second electronic elements;
wherein retrieving the position information of the at least one electronic element at least comprises retrieving position information of at least one first electronic element in the plurality of first electronic elements;
wherein comparing the position information of the at least one electronic element with the reference value at least comprises comparing the position information of the at least one first electronic element with position information of a position comparison reference to obtain a first shift amount of the shift amount.

18. The manufacturing method of the electronic device of claim 17, wherein the plurality of contact portions comprise a plurality of first contact portions in contact with a plurality of first pads of the plurality of first electronic elements and a plurality of second contact portions in contact with a plurality of second pads of the plurality of second electronic elements, and a position of each of the plurality of first contact portions and each of the plurality of second contact portions is compensated according to the first shift amount.

19. The manufacturing method of the electronic device of claim 17, wherein retrieving the position information of the at least one electronic element further comprises retrieving position information of at least one second electronic element in the plurality of second electronic elements;
wherein comparing the position information of the at least one electronic element with the reference value further comprises comparing the position information of the at least one second electronic element with the position information of the at least one first electronic element or comparing with the position information of the position comparison reference to obtain a second shift amount of the shift amount;
wherein the plurality of contact portions comprise a plurality of first contact portions in contact with a plurality of first pads of the plurality of first electronic elements and a plurality of second contact portions in contact with a plurality of second pads of the plurality of second electronic elements, a position of each of the plurality of first contact portions is compensated according to the first shift amount, and a position of each of the plurality of second contact portions is compensated according to the second shift amount.
